(19) United States
(12) Patent Application Publication
(10) Pub. No.: US 2017/0107640 A1
(43) Pub. Date: Apr. 20, 2017

(54) METHOD FOR FORMING MONOCRYSTALLINE SILICON INGOT AND WAFERS

(71) Applicant: ZING SEMICONDUCTOR CORPORATION, Shanghai (CN)

(72) Inventors: DEYUAN XIAO, Shanghai (CN); RICHARD R. CHANG, Shanghai (CN)

(21) Appl. No.: 15/178,080

(22) Filed: Jun. 9, 2016

(30) Foreign Application Priority Data
Oct. 15, 2015 (CN) 201510672144.6

(51) Int. Cl. C30B 15/22; C30B 29/06; C30B 33/00; C30B 15/04

(52) U.S. Cl. CPC C30B 15/22; C30B 15/04; C30B 29/06; C30B 33/00

(57) ABSTRACT

The present invention relates to a method for forming monocrystalline silicon ingot and wafers. At first, silica is doped with deuterium atoms which is retained in interstices therein. Then, the silica doped with deuterium atoms is utilized for a Czochralski method to form an ingot, which has few oxygen and impurities. The ingot then is utilized to form a wafer. When semiconductor devices are formed on the wafer, the deuterium atoms therein spread out and bind to dangling bonds around the interface to form a relatively stable structure. Therefore, hot carriers may be avoided, leakage may be lowered, and performance and reliability may be promoted.

### FIELD OF THE INVENTION

The present invention relates to a field of forming monocrystalline silicon ingot and semiconductor manufacturing, and especially to a method for forming monocrystalline silicon ingot and wafers.

### BACKGROUND OF THE INVENTION

Monocrystalline silicon ingots, formed by Czochralski (CZ) method, a technology to grow cylindrical single crystal silicon, are served as raw materials for manufacturing semiconductor devices. The ingots are sliced, etched, cleaned, polished to form wafers.

According to the CZ method, polysilicon is heated to be melted in a crucible, a rod-like seed crystal, about 10 mm in diameter, is then soaked in the melted polysilicon. When the seed crystal is rotated and lifted gradually, the single crystal is grown with continued lattices by silicon atoms in the melted polysilicon. If the environment is stable, the crystallization is carried out stably, and then eventually, a monocrystalline silicon ingot, cylindrical single crystal silicon, is formed.

The melted polysilicon usually gets polluted in the quartz crucible. Oxygen atoms, one of the pollutants, penetrate into the lattices to a predetermined concentration, which depends on solubility of oxygen in silicon at a temperature of the melted polysilicon and real segregation coefficient of oxygen in solid silicon. The concentration of the penetrated oxygen in the ingot is greater than the solubility of the oxygen in the solid silicon at a typical temperature in the fabrication process. The solubility of oxygen is decreased rapidly as the crystal is cooled, and then the solubility of oxygen is saturated in the ingot.

The ingot is then sliced into wafers. The interstitial oxygen atoms inside wafers form oxygen precipitations in the later thermal process. If these oxygen precipitations are located in an active region of semiconductor devices, the integrity of the gate oxide may be damaged and undesirable leakage current may be allowed.

### SUMMARY OF THE INVENTION

An object of the present invention is to provide a method for forming monocrystalline silicon ingot and wafer, through the method, oxygen and carbon impurities may be reduced and the performance of semiconductor devices formed afterwards may be promoted.

The present invention provides a method for forming monocrystalline silicon ingot, comprising steps of providing a silica which is doped with deuterium atoms; and melting the doped silica as a raw doping material along with a polysilicon material, which are mixed together, by applying a Czochralski method to form an ingot.

Further, when doping the silica with the deuterium atoms, optionally, the dosage of the deuterium atoms may be within 1E12-1E18 ions/cm², and/or the energy of the deuterium atoms may be within 1 keV-100 keV.

In the method for forming monocrystalline silicon ingot, the Czochralski method may be optionally exemplified by comprising steps of: melting the doped silica along with the polysilicon material in the crucible at a predetermined temperature; pulling a seed crystal dipped into the melted polysilicon fragments with a predetermined pull rate to grow a single crystal, and slowing the pull rate to transit to a shoulder stage when a neck length of the single crystal reaching a predetermined length; maintaining a linear cooling rate with the slowed pull rate in the shoulder stage, forming a predetermined diameter for the ingot, and then transiting to a constant-diameter growth stage; and when the diameter of the ingot reaching the predetermined diameter, pulling the single crystal up rapidly with cooling but stopping linear cooling and lifting the crucible with a lifting rate, slowly adjusting the pull rate according to the diameter variety rate, and executing an automatic constant-diameter growth program to transit to an automatic constant-diameter growth stage after stabilizing the diameter of the ingot.

Further, in the method for forming monocrystalline silicon ingot, the diameter of the ingot may be optionally controlled through the pull rate and the predetermined temperature, and the silica may be optionally chosen from polysilicon, and the like.

According to the present invention, a method for forming monocrystalline silicon wafer is provided. An ingot which is formed according to the aforesaid method is utilized as a material to form at least one wafer.

In the method for forming monocrystalline silicon wafer, further steps of slicing, grinding, polishing, surface profiling and cleaning may be comprised to turn the ingot into wafer(s).

The present invention may be beneficial to but not limited to: reducing the content of the oxygen and other impurities mixed in the ingot, resulted from the deuterium atoms, which comes from the silica doped with the interstitial deuterium atoms, as the raw doping material to form the ingot in the Czochralski method, in the ingot; strengthening the resistance to hot carriers, lowering leakage current, and promoting the performance and reliability of the semiconductor devices, resulted from the decreasing of the dangling bonds in that the interstitial deuterium atoms are diffused to bind to the dangling bonds in a process for forming the semiconductor devices.

### BRIEF DESCRIPTION OF THE DRAWINGS

Various objects and advantages of the present invention will be more readily understood from the following detailed description when read in conjunction with the appended drawing, in which:

FIG. 1 shows a flow chart of a method for forming monocrystalline silicon ingot according to an embodiment of the invention.

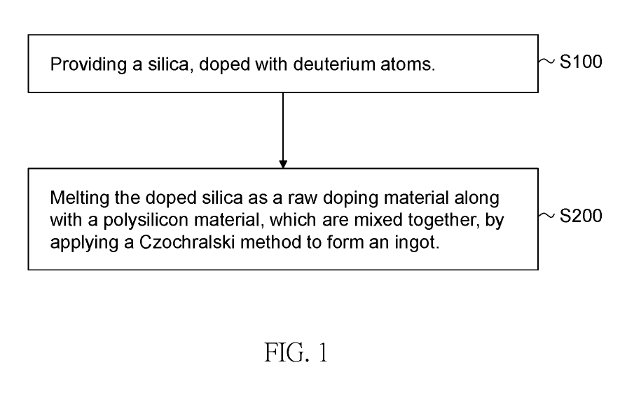

### DESCRIPTION OF EMBODIMENTS OF THE INVENTION

For a more complete understanding of the present disclosure and its advantages, reference is now made to the following description taken in conjunction with the accompanying drawings, in which like reference numbers indicate like features. Persons having ordinary skill in the art will understand other varieties for implementing example embodiments, including those described herein. The drawings are not limited to specific scale and similar reference numbers are used for representing similar elements. As used in the disclosures and the appended claims, the terms “example embodiment,” “exemplary embodiment,” and “present embodiment” do not necessarily refer to a single embodiment, although it may, and various example embodiments may be readily combined and interchanged, without departing from the scope or spirit of the present disclosure. Furthermore, the terminology as used herein is for the purpose of describing example embodiments only and is not intended to be a limitation of the disclosure. In this respect, as used herein, the term “in” may include “in” and “on”, and the terms “a”, “an” and “the” may include singular and plural references. Furthermore, as used herein, the term “by” may also mean “from”, depending on the context. Furthermore, as used herein, the term “if” may also mean “when” or “upon”, depending on the context. Furthermore, as used herein, the words “and/or” may refer to and encompass any and all possible combinations of one or more of the associated listed items.

According to an embodiment of the present invention, a method for forming monocrystalline silicon ingot is provided. The method comprises step S100: providing a silica which is doped with deuterium atoms, and step S200: melting the doped silica as a raw doping material along with a polysilicon material, which are mixed together, by applying a Czochralski method to form an ingot.

In the step S100, the silica may be chosen from monocrystalline silicon, silica with impurities and the like. Before a Czochralski method is applied, the silica is doped with deuterium atoms to form interstitial deuterium atoms therein. Then the content of the oxygen and other impurities in the silica is reduced to raise the potential to promote the performance and reliability of semiconductor devices formed through wafer(s) produced by the ingot. Further, when doping the silica with the deuterium atoms, for example, the dosage of the deuterium atoms may be within 1E12-1E18 ions/cm², and preferably 1E15 ions/cm².

Further, when doping the silica with the deuterium atoms, the energy of the deuterium atoms may be within 1 keV-100 keV, and preferably, 50 keV. Please note that the specific energy or dosage may be varied according to the size of the silica.

In the step S200, the doped silica is served as a raw doping material for a Czochralski method to form the ingot. Specifically, the Czochralski method may comprise: putting the doped silica in the crucible to be melted along with the polysilicon material at a predetermined temperature; pulling a seed crystal dipped into the melted materials with a predetermined pull rate to grow a single crystal, and slowing down the pull rate to transit to a shoulder stage when a neck length of the single crystal reaching a predetermined length; maintaining a linear cooling rate with the slowed pull rate in the shoulder stage, forming a predetermined diameter for the ingot, and then transiting to a constant-diameter growth stage; and when the diameter of the ingot reaching the predetermined diameter, pulling the single crystal up rapidly with cooling but stopping linear cooling and lifting the crucible with a lifting rate, slowly adjusting the pull rate according to the diameter variety rate, and executing an automatic constant-diameter growth program to transit to an automatic constant-diameter growth stage after stabilizing the diameter of the ingot. Further, the diameter of the ingot may be optionally controlled through the pull rate and the predetermined temperature, and designed according to process requirement.

According to the present invention, a method for forming monocrystalline silicon wafer is further provided. An ingot which is formed according to the aforesaid method is utilized as a material to form a wafer. Specifically, further steps of slicing, grinding, polishing, surface profiling and cleaning may be executed to turn the ingot into wafers. Then, semiconductor devices may be formed on the wafer. Because of the deuterium atoms received in the interstice sites and the low content of the oxygen atoms and other impurities in the wafer, oxygen precipitations which usually occur in a thermal process may be significantly reduced to protect the integrity of gate oxide in a device active region and avoid from unnecessary leakage current.

To sum up, in the method for forming monocrystalline silicon ingot and wafer of the embodiments according to the present invention, the content of the oxygen and other impurities mixed in the ingot may be reduced, resulted from the deuterium atoms, which comes from the silica doped with the interstitial deuterium atoms, as the raw doping material to form the ingot in the Czochralski method, in the ingot; the resistance to hot carriers may be strengthened, leakage current may be lowered, and the performance and reliability of the semiconductor devices may be promoted, resulted from the decreasing of the dangling bonds in that the interstitial deuterium atoms are diffused to bind to the dangling bonds in a process for forming the semiconductor devices.

While various embodiments in accordance with the disclosed principles been described above, it should be understood that they are presented by way of example only, and are not limiting. Thus, the breadth and scope of exemplary embodiment(s) should not be limited by any of the above-described embodiments, but should be defined only in accordance with the claims and their equivalents issuing from this disclosure. Furthermore, the above advantages and features are provided in described embodiments, but shall not limit the application of such issued claims to processes and structures accomplishing any or all of the above advantages.

Additionally, the section headings herein are provided for consistency with the suggestions under 37 C.F.R. 1.77 or otherwise to provide organizational cues. These headings shall not limit or characterize the invention(s) set out in any claims that may issue from this disclosure. Specifically, a description of a technology in the “Background” is not to be construed as an admission that technology is prior art to any invention(s) in this disclosure. Furthermore, any reference in this disclosure to “invention” in the singular should not be used to argue that there is only a single point of novelty in this disclosure. Multiple inventions may be set forth according to the limitations of the multiple claims issuing from this disclosure, and such claims accordingly define the invention(s), and their equivalents, that are protected thereby. In all instances, the scope of such claims shall be considered on their own merits in light of this disclosure, but should not be constrained by the headings herein.

What is claimed is:

1. A method for forming monocrystalline silicon ingot, comprising:
providing a silica, doped with deuterium atoms; and
melting the doped silica as a raw doping material along with a polysilicon material, which are mixed together, by applying a Czochralski method to form an ingot.

2. The method for forming monocrystalline silicon ingot as claim 1, wherein when doping the silica with the deuterium atoms, the dosage of the deuterium atoms is within 1E12-1E18 ions/cm².

3. The method for forming monocrystalline silicon ingot as claim 2, wherein when doping the silica with the deuterium atoms, the energy of the deuterium atoms is within 1 keV-100 keV.

4. The method for forming monocrystalline silicon ingot as claim 1, wherein Czochralski method comprises steps of:
melting the doped silica along with the polysilicon material in the crucible at a predetermined temperature;
pulling a seed crystal dipped into the melted polysilicon fragments with a predetermined pull rate to grow a single crystal, and slowing the pull rate to transit to a shoulder stage when a neck length of the single crystal reaching a predetermined length;
maintaining a linear cooling rate with the slowed pull rate in the shoulder stage, forming a predetermined diameter for the ingot, and then transiting to a constant-diameter growth stage; and
when the diameter of the ingot reaching the predetermined diameter, pulling the single crystal up rapidly with cooling but stopping linear cooling and lifting the crucible with a lifting rate, slowly adjusting the pull rate according to the diameter variety rate, and
executing an automatic constant-diameter growth program to transit to automatic constant-diameter growth stage after stabilizing the diameter of the ingot.

5. The method for forming monocrystalline silicon ingot as claim 4, wherein a diameter of the ingot is controlled through the pull rate and the predetermined temperature.

6. The method for forming monocrystalline silicon ingot as claim 1, wherein the silica is monocrystalline silicon.

7. The method for forming monocrystalline silicon ingot as claim 1, wherein the silica is a polysilicon.

8. A method for forming monocrystalline silicon wafer, wherein an ingot which is formed according to the method as claimed in claims 1 is utilized as a raw material to form a wafer.

9. The method for forming monocrystalline silicon wafer as claim 8, further comprising steps of executing slicing, grinding, polishing, surface profiling and cleaning to turn the ingot into the wafer.
